(19) United States
(12) Patent Application Publication
(10) Pub. No.: US 2017/0105292 A1
(43) Pub. Date: Apr. 13, 2017

(54) LAPTOP COMPUTER COVER

(71) Applicant: KUZY LLC, Meridian, ID (US)

(72) Inventor: Petr Kuzmenko, Meridian, ID (US)

(21) Appl. No.: 14/877,842

(22) Filed: Oct. 7, 2015

(51) Int. Cl. H05K 5/00; H05K 5/02

(52) U.S. Cl. CPC H05K 5/0017; H05K 5/0086; H05K 5/02; H05K 5/0234; H05K 5/0013

(57) ABSTRACT

A laptop computer cover has a rigid inner layer and a soft silicone outer layer. The laptop computer cover includes a display portion cover and a keyboard portion cover. In one embodiment, the display portion cover can be placed on an outside surface of a display portion of a laptop computer and the keyboard portion cover can be placed on an outside surface of the keyboard portion of the laptop computer. Some embodiments of the display portion cover and keyboard portion cover each include a raised edge along a portion of their respective perimeters. The inner rigid layer may be made of various types of plastic or other rigid materials. The outer soft silicone layer may be fixed to the inner rigid layer with an adhesive.

### BACKGROUND

Technical Field

The present disclosure relates generally to an accessory for a laptop or other computer device. In particular, the present disclosure relates to a cover for laptop computers.

Description of Related Art

Since users often carry around their laptops for use in a variety of locations, the exterior surfaces of a laptop computer may get scratched, dented, cracked, or otherwise acquire wear and tear.

Laptop computer covers are commonly used to protect laptop computers. Many laptop computer covers are manufactured from plastic, which may be unsightly, slippery, and thus prone to accidental dropping, flimsy, and otherwise susceptible to a low quality feel.

Another reason people may choose to use laptop covers on their laptop computers is to customize the appearance of the laptop computer, which may otherwise have a similar appearance to many other laptops. Many laptop users may desire to express their individuality by using a laptop cover having the aesthetic qualities specifically selected by the user.

However, because many laptop computer covers that are currently available may exhibit a low quality appearance and feel, the laptop users may remain unsatisfied with the laptop covers.

### SUMMARY

In one embodiment, a laptop computer cover is disclosed. The laptop computer cover has a display portion cover for attaching to a display portion of a laptop computer, and a keyboard portion cover for attaching to a keyboard portion of the laptop computer. The display portion cover includes a display portion rigid inner layer adhered to a display portion silicone outer layer. The keyboard portion cover includes a keyboard portion rigid inner layer adhered to a keyboard portion silicone outer layer.

In another embodiment, a method of manufacturing a laptop computer cover is disclosed. The method includes molding a first rigid layer to fit a laptop display portion, fitting a first silicone layer to the first rigid layer, molding a second rigid layer to fit a laptop keyboard portion, fitting a second silicone layer to the second rigid layer, adhering the first silicone layer to the first rigid layer; and adhering the second silicone layer to the second rigid layer.

In another embodiment, a laptop computer cover is disclosed. The laptop computer cover includes a display portion cover and a keyboard portion cover. The display portion cover has a first rigid inner layer and a first silicone outer layer. The keyboard portion cover has a second rigid inner layer and a second silicone outer layer.

The present disclosure will now be described more fully with reference to the accompanying drawings, which are intended to be read in conjunction with both this summary, the detailed description, and any preferred or particular embodiments specifically discussed or otherwise disclosed. This disclosure may, however, be embodied in many different forms and should not be construed as limited to the embodiments set forth herein; rather, these embodiments are provided by way of illustration only so that this disclosure will be thorough, and fully convey the full scope of the invention to those skilled in the art.

### BRIEF DESCRIPTION OF THE DRAWINGS

Non-limiting and non-exhaustive embodiments of the present disclosure are described with reference to the following figures, wherein like reference numerals refer to like parts throughout the various views unless otherwise specified.

FIG. 1 is an illustration of a laptop computer cover and a laptop computer in accordance with one embodiment of the present disclosure;

FIG. 2 is a perspective view of a laptop cover attached to the laptop computer according to one embodiment of the present disclosure;

FIG. 3 depicts a display portion cover according to an embodiment of the present disclosure;

FIG. 4 depicts the underside of a keyboard portion cover according to an embodiment of the present disclosure;

FIG. 5 is a cross-sectional detail view depicting layers of a laptop cover according to embodiments of the present disclosure;

FIG. 6 depicts a manufacturing step for a display portion cover according to an embodiment of the present disclosure; and

FIG. 7 depicts a manufacturing step for a keyboard portion cover according to an embodiment of the present disclosure.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present disclosure. Also, common but well-understood elements that are useful or necessary in a commercially feasible embodiment are often not depicted in order to facilitate a less obstructed view of these various embodiments of the present disclosure.

### DETAILED DESCRIPTION

In the following description, reference is made to exemplary embodiments in which the disclosure may be practiced. These embodiments are described in sufficient detail to enable those skilled in the art to practice the concepts disclosed herein, and it is to be understood that modifications to the various disclosed embodiments may be made, and other embodiments may be utilized, without departing from the spirit and scope of the present disclosure. The following detailed description is, therefore, not to be taken in a limiting sense.

Reference throughout this specification to “one embodiment,” “an embodiment,” “one example,” or “an example” means that a particular feature, structure, or characteristic described in connection with the embodiment or example is included in at least one embodiment of the present disclosure. Thus, appearances of the phrases “in one embodiment,” “in an embodiment,” “one example,” or “an example” in various places throughout this specification are not necessarily all referring to the same embodiment or example. Furthermore, the particular features, structures, or characteristics may be combined in any suitable combinations and/or sub-combinations in one or more embodiments or examples.

Embodiments of the present disclosure include silicone laptop covers for various other types of electronic devices. Such devices may include, but are not limited to smart phones, personal music players, and other handheld electronic devices. Embodiments include an exterior cover for laptop computers having comprises a separate upper element that may be applied to the outside surface of the display portion of the laptop computer and a separate lower piece that may be applied to the outside surface of the keyboard portion of the laptop computer. Embodiments can snap onto the laptop computer using a one or more tabs that grip corresponding surfaces of the laptop computer, which may provide for convenient application and removal.

Embodiments of the upper piece of the laptop cover comprise a relatively planar element that is shaped to form fit to an exterior surface of a laptop display portion. Embodiments of the lower piece of the laptop cover comprise a relatively planar element that is shaped to form fit to an exterior surface of a laptop keyboard portion. In embodiments, the upper piece and the lower piece are rigid essentially planar elements having raised edges that cover portions of the sides of the laptop display portion and the laptop keyboard portion, respectively.

In general, the upper piece of the laptop cover and the lower piece of the laptop cover each comprise a layered construction including a soft silicone outer layer adhered to a rigid inner layer. In embodiments, the rigid inner layer provides the shape to the upper piece of the laptop cover and the lower piece of the laptop cover. In embodiments, the silicone outer layer is manufactured from a flexible sheet of silicone that may conform to the shape of the rigid inner layer to which it is adhered.

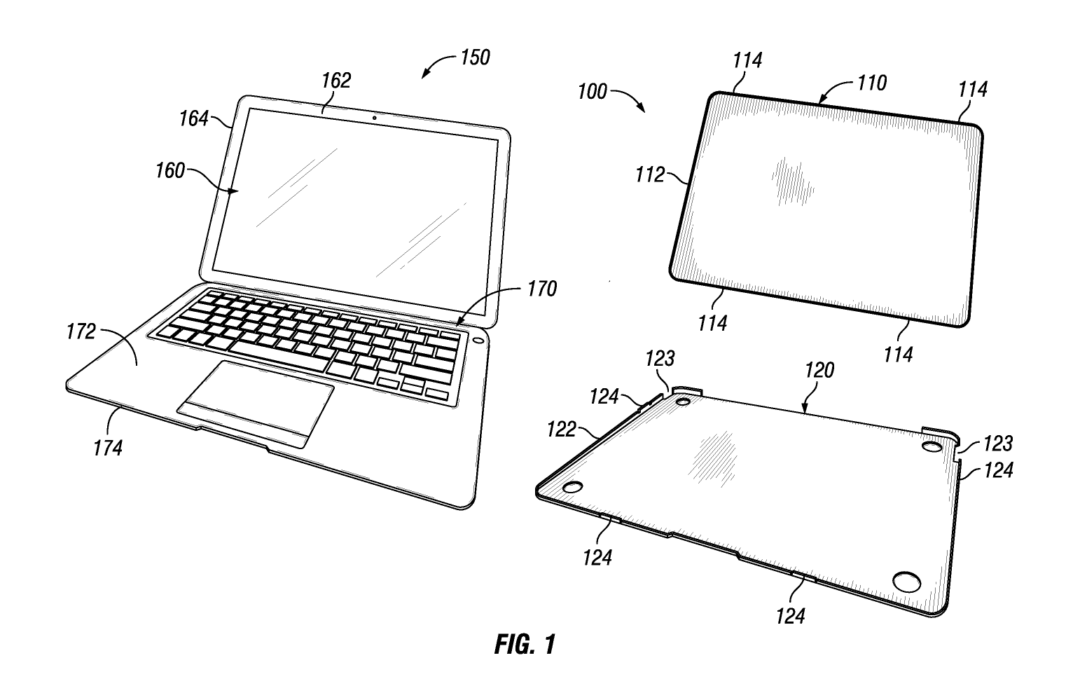

FIG. 1 is an illustration of a perspective view of an exterior cover 100 for a laptop computer in accordance with one embodiment of the present disclosure. FIG. 1 depicts a laptop computer 150 having a display portion 160 and a keyboard portion 170. Display portion 160 comprises an inside bezel surface 162 and an outside surface (not shown) located on the opposite as inside bezel surface 162. Display portion 160 further comprises peripheral surfaces 164. Keyboard portion 170 includes inside bezel surface 172 and outside surface (not shown) located on the opposite as inside bezel surface 172. Keyboard portion 170 further comprises peripheral surfaces 174.

FIG. 1 further shows a display portion cover 110 that may be applied to the outside surface of the display portion 160 of the laptop computer 150. In one embodiment, display portion cover 110 comprises a rigid planar sheet that is substantially rectangular with rounded corners. Other embodiments comprise a display portion cover that has a shape essentially mated to the shape of the display portion of the particular model of laptop computer for which cover 100 was designed. In various embodiments, display portion cover 110 comprises a raised edge 112 disposed around the circumference or perimeter, or a part thereof, of display portion cover 110. Embodiments of raised edge 112 extend perpendicularly from the display portion cover 110 as depicted in FIG. 1.

According to various embodiments of the present disclosure, display portion cover 110 further includes a plurality of tabs 114 located along raised edge 112. In one embodiment, each of the plurality of tabs 114 comprises a protruding element that extends essentially perpendicularly from raised edge 112 on the inside facing edge of raised edge 112. Tabs 114 may grip surfaces of display portion 160 to allow display portion cover 110 to snap onto display portion 160 of laptop computer 150.

FIG. 1 further shows a separate, or independent, keyboard portion cover 120 for applying to the outside surface of the keyboard portion 170 of the laptop computer 150. In one embodiment, keyboard portion cover 120 comprises a rigid planar sheet that is substantially rectangular with rounded corners. Other embodiments comprise a keyboard portion cover that has a shape essentially mated to the shape of the keyboard portion of the particular model of laptop computer for which cover 100 was designed. In various embodiments, keyboard portion cover 120 comprises a raised edge 122 disposed around the circumference or perimeter, or a part thereof, of keyboard portion cover 120. Embodiments of raised edge 122 extend perpendicularly from the keyboard portion cover 120 as depicted in FIG. 1.

According to various embodiments of the present disclosure, keyboard portion cover 120 further includes a plurality of tabs 124 located along raised edge 122. In one embodiment, each of the plurality of tabs 124 comprises a protruding element that extends essentially perpendicularly from raised edge 122 on the inside facing edge of raised edge 122. Tabs 124 may grip surfaces of keyboard portion 170 to allow keyboard portion cover 120 to snap onto keyboard portion 170 of laptop computer 150.

Embodiments of display portion cover 110 and/or keyboard portion cover 120 are malleable and/or elastic to allow for tabs 114, 124 to be pushed back or away from the laptop peripheral surfaces 164 and/or 174 without breaking tabs 114, 124, while allowing for tabs 114, 124 to return to their initial shape or position after the laptop computer 150 is inserted into the laptop cover 100.

One embodiment of keyboard portion cover 120 has raised edge 122 with openings 123. Openings 123 comprise sections where either there is a relatively low section of raised edge 122 or there is no raised edge 122. Openings 123 can provide an open area for a movable part, such as a hinge connecting the keyboard portion 170 with display portion 160 and/or provide access to various features of keyboard portion 170 such as a power connection port, a data port, a button, and a removable media drive.

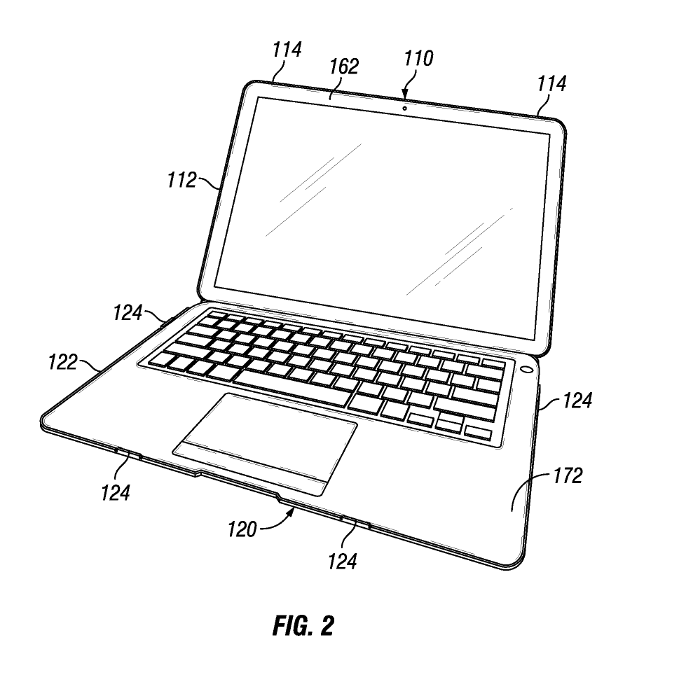

FIG. 2 is an illustration of a perspective view of a laptop cover attached to a laptop computer. FIG. 2 depicts display portion cover 110 attached to the display portion and keyboard portion cover 120 attached to the keyboard portion. In embodiments, covers 110 and 120 can be attached to the laptop computer while the laptop computer is either in the open or closed position.

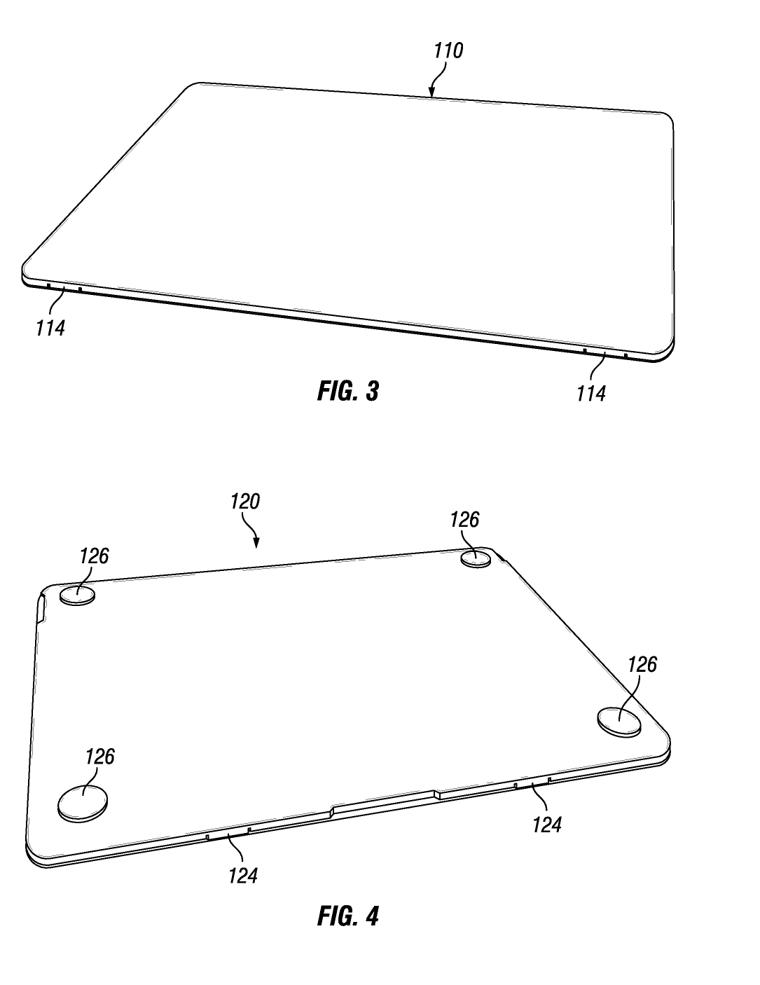

FIG. 3 depicts a top surface of display portion cover 110. Referring now to FIG. 4, the underside of an embodiment of keyboard portion cover 120 comprises feet 126 on the bottom surface thereof. According to various embodiments, feet 126 comprise a downward-facing protrusion from the bottom surface of keyboard portion cover 120. In embodiments, feet 126 can provide stability, can increase friction between the laptop 150 and the surface upon which it rests, and/or increase the space between the laptop 150 and the surface upon which it rests. In embodiments, feet 126 are provided shape by the rigid inner layer of cover 100 and the soft silicone outer layer, with both layers comprising foot protrusions. In one embodiment, the silicone outer layer comprises indentations to receive the corresponding downward-facing protrusions of the rigid inner layer.

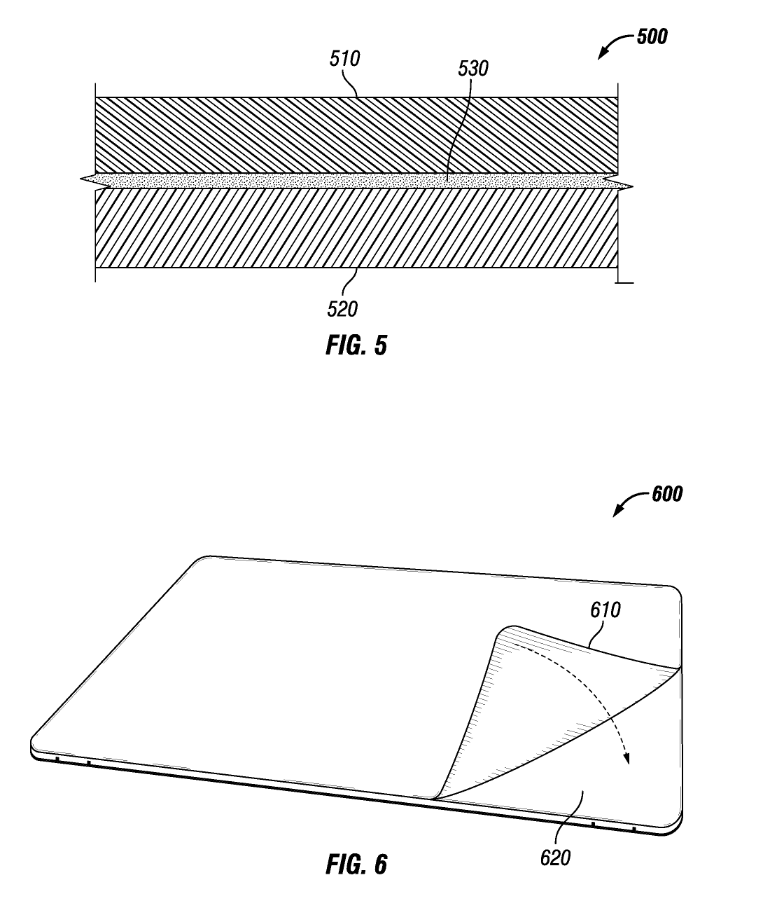

FIG. 5 is a cross-sectional detail view of a portion of a laptop cover 500 comprising a soft silicone outer layer 510 adhered to a rigid inner layer 520. In embodiments, both display portion cover 110 and keyboard portion cover 120 comprise outer layer 510 and inner layer 520. In one embodiment, adhesive layer 530 maintains layers 510 and 520 secured to each other. In various embodiments, adhesive 530 comprises one or more selected from a variety of epoxies, pastes, bonding agents, silicone adhesives, other types of adhesives, or combinations thereof. In one embodiment, outer layer 510 and inner layer 520 have roughly equal thicknesses. In another embodiment, the rigid inner layer has a thickness of between roughly equal to the thickness of the outer layer to roughly double the thickness of the outer layer. In one embodiment, outer layer 510 has a thickness of approximately 1 mm and inner layer 520 has a thickness of approximately 1 mm.

In embodiments, silicone outer layer 510 may be manufactured from various formulations of silicone (polymerized siloxanes) materials such as silicone rubber. In embodiments, silicone outer layer 510 comprises a soft, flexible sheet of silicone or a material of which silicone is a component.

In embodiments, inner layer 520 may be manufactured from a variety of materials including metal, such as stainless steel, titanium, aluminum or any metal alloy, rigid fabric, carbon fiber, epoxy resin, graphite, rubber, plastic, or any combination of the above. Plastic inner layers may comprise materials selected from a range of synthetic or semi-synthetic polymerization products, including but not limited to: polyethylene, polystyrene, high impact polystyrene, polyethylene terephthalate, nylon, polypropylene, acrylonitrile butadiene styrene (“ABS”), and polyvinyl chloride (“PVC”).

In embodiments, inner layer 520 may be manufactured from a plastic compound using any variety of processes, such as injection molding, fusible core injection molding, and thermoforming. According to embodiments, the display portion cover may be manufactured to have a shape essentially mated to the shape of the display portion of the particular model of laptop computer for which the display portion cover was designed. In other words, the dimensions between raised edges of the display portion cover may be slightly greater than the size of a laptop computer display portion, such that the display portion cover can receive the laptop computer display portion. Likewise, the keyboard portion cover may be manufactured to have a shape essentially mated to the shape of the keyboard portion of the particular model of laptop computer for which the keyboard portion cover was designed. In other words, the dimensions between raised edges of the keyboard portion cover may be slightly greater than the size of a laptop computer keyboard portion, such that the keyboard portion cover can receive the laptop computer keyboard portion.

Referring to FIG. 6, a display portion cover 600 may be manufactured by forming a sheet of flexible silicone 610 to have roughly the dimensions of a desired display portion cover 600, according to the dimensions of a selected model of laptop computer. A rigid inner layer 620 may be manufactured by forming a rigid substrate into roughly the dimensions and shape of a desired display portion cover 600, according to the dimensions of a selected model of laptop computer. The flexible silicone sheet 610 may then be adhered to the rigid inner layer 620 by applying an adhesive therebetween. The adhesive may be sprayed, brushed, and/or otherwise applied to one or both layers 610, 620. The flexible silicone sheet 610 may be stretched, if needed, to fit inner layer 620. In one embodiment, after the silicone sheet 610 has been adhered to the rigid inner layer 620, the edges of the silicone sheet 610 can be trimmed. In one embodiment, after adhering layers 610, 620 together, edges, including tabs 114, of both layers 610, 620 are cut to a specified size and shape according to the dimensions of the selected model of laptop computer for which the laptop cover was designed.

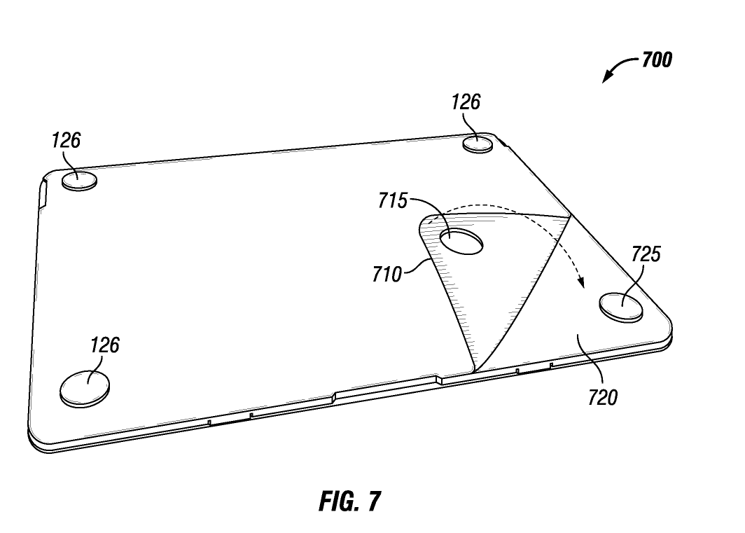

Referring to FIG. 7, a keyboard portion cover 700 may be manufactured by forming a sheet of flexible silicone 710 to have roughly the dimensions of a desired keyboard portion cover 700, according to the dimensions of a selected model of laptop computer. A rigid inner layer 720 may be manufactured by forming a rigid substrate into roughly the dimensions and shape of a desired keyboard portion cover 700, according to the dimensions of a selected model of laptop computer. The flexible silicone sheet 710 may then be adhered to the rigid inner layer 720 by applying an adhesive therebetween. The adhesive may be sprayed, brushed, and/or otherwise applied to one or both layers 710, 720. The flexible silicone sheet 710 may be stretched, if needed, to fit inner layer 720. In one embodiment, flexible silicone sheet 710 comprises indentations 715 to receive the corresponding downward-facing protrusions 725 of the rigid inner layer 720. In one embodiment, after the silicone sheet 710 has been adhered to the rigid inner layer 720, the edges of the silicone sheet 710 can be trimmed. In one embodiment, after adhering layers 710, 720 together, edges, including tabs 124, of both layers 710, 720 are cut to a specified size and shape according to the dimensions of the selected model of laptop computer for which the laptop cover was designed.

Embodiments of silicone sheets 610, 710 include raised edges around their perimeters or around parts of their perimeters. In such embodiments, raised edges of silicone sheets 610, 710 can be adhered to raised edges 112, 124 of rigid inner layers 620, 730.

Some embodiments of the present disclosure include preparing the surface of the rigid inner layer 620 or 720 prior to adhering it to silicone layer 610 or 710 by applying a primer or other preparatory coating. In other embodiments, the surface of the rigid inner layer 620 or 720 can be prepared by roughening the surface, such as by sanding the surface. In embodiments, the adhesive is cured at room temperature or by subjecting the cover 600, 700 to elevated heat. In other embodiments, other methods for curing the adhesive can be carried out.

Although the present disclosure is described in terms of certain embodiments, other embodiments will be apparent to those of ordinary skill in the art, given the benefit of this disclosure, including embodiments that do not provide all of the benefits and features set forth herein, which are also within the scope of this disclosure. It is to be understood that other embodiments may be utilized, without departing from the spirit and scope of this disclosure.

1. A laptop computer cover, comprising:
a display portion cover for attaching to a display portion of a laptop computer;
a keyboard portion cover for attaching to a keyboard portion of the laptop computer;
wherein:
the display portion cover comprises a display portion silicone outer layer fitted and adhered to a display portion rigid inner layer and
the keyboard portion cover comprises a keyboard portion silicone outer layer fitted and adhered to a keyboard portion rigid inner layer.

2. The laptop computer cover of claim 1, wherein the display portion cover comprises a raised edge along a perimeter of the display portion.

3. The laptop computer cover of claim 2, further comprising inward-facing tabs on the raised edge.

4. The laptop computer cover of claim 1, wherein the keyboard portion cover comprises a raised edge along a perimeter of the keyboard portion.

5. The laptop computer cover of claim 4, further comprising inward-facing tabs on the raised edge.

6. The laptop computer cover of claim 1, wherein the keyboard portion cover further comprises feet on a bottom surface.

7. The laptop computer cover of claim 1, wherein:
the keyboard portion rigid inner layer comprises multiple downward-facing protrusions;
the keyboard portion silicone outer layer comprises multiple downward-facing protrusions matching the downward-facing protrusions of the keyboard portion rigid inner layer.

8. The laptop computer cover of claim 7, wherein the silicone outer layer comprises multiple indentations on an upper-facing surface adapted to receive the downward-facing protrusions of the keyboard portion rigid inner layer.

9. The laptop computer cover of claim 1, wherein the display portion rigid inner layer comprises a plastic material.

10. The laptop computer cover of claim 1, wherein the keyboard portion rigid inner layer comprises a plastic material.

11. The laptop computer cover of claim 1, further comprising inward-facing tabs on the display portion cover.

12. The laptop computer cover of claim 1, further comprising inward-facing tabs on the keyboard portion cover.

13. A method of manufacturing a laptop computer cover, comprising:
providing a first rigid layer to fit a laptop display portion;
fitting a first silicone layer to the first rigid layer;
providing a second rigid layer to fit a laptop keyboard portion;
fitting a second silicone layer to the second rigid layer;
adhering the first silicone layer to the first rigid layer; and
adhering the second silicone layer to the second rigid layer.

14. The method of claim 13, wherein adhering the first silicone layer to the first rigid layer comprises applying an adhesive to the first rigid layer and setting the first silicone layer on the first rigid layer.

15. The method of claim 13, wherein adhering the second silicone layer to the second rigid layer comprises applying an adhesive to the second rigid layer and setting the second silicone layer on the second rigid layer.

16. The method of claim 13, further comprising curing an adhesive.

17. The method of claim 13, further comprising:
following adhering the first silicone layer to the first rigid layer and adhering the second silicone layer to the second rigid layer, trimming an overhanging portion of the first silicone layer and an overhanging portion of the second silicone layer.

18. A laptop computer cover comprising:
a display portion cover having a first silicone outer layer fitted and adhered to a first rigid inner layer and
a keyboard portion cover having a second silicone outer layer fitted and adhered to a second rigid inner layer.

19. The laptop computer cover of claim 18, wherein the first rigid inner layer and the second rigid inner layer each comprise a plastic material.

20. The laptop computer cover of claim 18, wherein:
the display portion cover comprises a first raised edge along a perimeter of the display portion cover and
the keyboard portion cover comprises a second raised edge along a perimeter of the keyboard portion cover.
